(19) United States
(12) Patent Application Publication
(10) Pub. No.: US 2010/0284154 A1
(43) Pub. Date: Nov. 11, 2010

(54) MODULAR SENSOR MOTE

(75) Inventors: Simon Caron, Quebec (CA); Simon Leblond, Quebec (CA)

Correspondence Address: Joseph Bain;Novak Druce & Quigg LLP, 525 Okeechobee Blvd, Suite 1500, West Palm Beach, FL, 33401, US

(73) Assignee: SCL Elements Inc., Montreal (CA)

(21) Appl. No.: 12/757,748

(22) Filed: Apr. 9, 2010

Related U.S. Application Data
(60) Provisional application No. 61/202,830, filed on Apr. 9, 2009.

(51) Int. Cl. H05K 7/02

(52) U.S. Cl. 361/728

(57) ABSTRACT

A modular sensor mote, comprising an electronic board having two connector portions with associated connectors, a wireless communication management portion, a power management portion and a sensor receiving portion adapted for receiving a sensor element.

### CROSS-REFERENCE TO RELATED APPLICATION

This application claims the benefit of U.S. provisional patent application No. 61/202,830 filed on Apr. 9, 2009, which is herein incorporated by reference.

### FIELD OF THE INVENTION

The present invention generally relates to a modular sensor mote.

### BACKGROUND OF THE INVENTION

Sensors are used in various apparatuses and/or systems to sense and detect physical stimulus. Each sensor is normally adapted to transmit a signal based on a precise physical stimulus to a control system. The control system is generally adapted to provide a reaction based on the signal. A retroaction loop can be implemented to continuously detect the physical stimulus and to provide continuous corrective actions based thereon.

For example, sensors are used to detect room temperature in buildings. A sensor installed to detect the temperature of a specific area of the building senses the temperature in the specific area. It routes a signal indicative of the temperature of the specific area to the temperature control system. The temperature control system is normally adapted to influence the sensed temperature of the specific area by heating or conditioning the air of the specific area based on the received signal. Heating or conditioning is stopped when the control system receives a signal from the sensor indicating that the desired temperature is reached at the specific area.

Typically, sensors are built to achieve a specific task. Various types of sensors are therefore required in a system designed to sense various conditions. For example, gas sensors can be installed in addition to temperature sensors in the same area. Both types of sensors are adapted to send a specific signal indicative of a certain stimulus to their related control systems. Thus, many different types of sensors are available for building a sensor network, which substantially increases the cost of inventory.

Sensors are generally adapted to be interconnected with wires to transmit theirs signals. The signal sent through a wire can use an arbitrary communication protocol adapted to transfer data over a wire. This communication protocol might influence the communication speed between the sensor and its associated control system. Alternatively, when a wired connection is not possible, the signal can be transmitted wirelessly. Again, a wireless communication protocol is required and might also influence the communication speed between the sensor and the control system.

Wireless communication is prone to interferences. This increases the risk of communication issues between sensors and their related control systems. Miscommunication between a sensor and its control system can have significant undesirable consequences and should be prevented.

Moreover, connectors embedded on sensors are intended to receive cooperating connectors thereto. A wire with an appropriate connector disposed on its end is commonly used to establish connection with the sensor. Connection to the connectors provides power and/or control signal transfer capability. Minimal, if any, mechanical load is sustained under normal use by the connector.

Therefore, there is a need for an improved structure to connect sensors. Also, an improved sensor adapted to be easily connectable is desirable. Additionally, an improved method to connect sensors has also been felt.

### SUMMARY OF THE INVENTION

According to one aspect of the present invention, there is provided a modular sensor mote, comprising:

an electronic board having:
at least one of a connector portion with an associated connector and a wireless communication management portion;
a power management portion; and
a sensor receiving portion adapted for receiving a sensor element;
   wherein the electronic board is adapted to electrically connect the connector portion, the power management portion and the sensor receiving portion.

According to another aspect of the present invention, the modular sensor mote comprises at least one connector portion with an associated connector and a wireless communication management portion.

According to a further aspect of the present invention, the modular sensor mote comprises two connector portions.

These and other advantages and features of the present invention will become apparent from the following description and the attached drawings.

### BRIEF DESCRIPTION OF THE DRAWINGS

Embodiments of the invention will be described by way of example only with reference to the accompanying drawings, in which:

FIG. 1 is a perspective view of a modular sensor mote in accordance with a first illustrative embodiment of the present invention;

FIG. 2 is a top plan view of the modular sensor mote of FIG. 1;

FIG. 3 is an exploded top perspective view of the modular sensor mote of FIG. 1;

FIG. 4 is an exploded bottom perspective view of the modular sensor mote of FIG. 1;

FIG. 5 is a top perspective view of the internal components of the modular sensor mote of FIG. 1;

FIG. 6 is a bottom perspective view of the opposite side of the internal components of FIG. 5;

FIG. 7 is a top perspective view of a modular sensor mote in accordance with a second illustrative embodiment of the present invention;

FIG. 8 is a top plan view of the modular sensor mote of FIG. 7;

FIG. 9 is an exploded top perspective view of the modular sensor mote of FIG. 7;

FIG. 10 is an exploded bottom perspective view of the modular sensor mote of FIG. 9;

FIG. 11 is a top plan view of an arbitrary arrangement of sensor motes;

FIG. 12 is a flow diagram of the process of connecting two or more modular sensor motes in accordance with an illustrative embodiment of the present invention;

FIG. 13 is an illustrative embodiment of a possible connection layout among sensor motes; and

FIG. 14 is an alternative illustrative embodiment of a possible connection layout among sensor motes.

### DESCRIPTION OF THE PREFERRED EMBODIMENTS

The present invention will now be described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details.

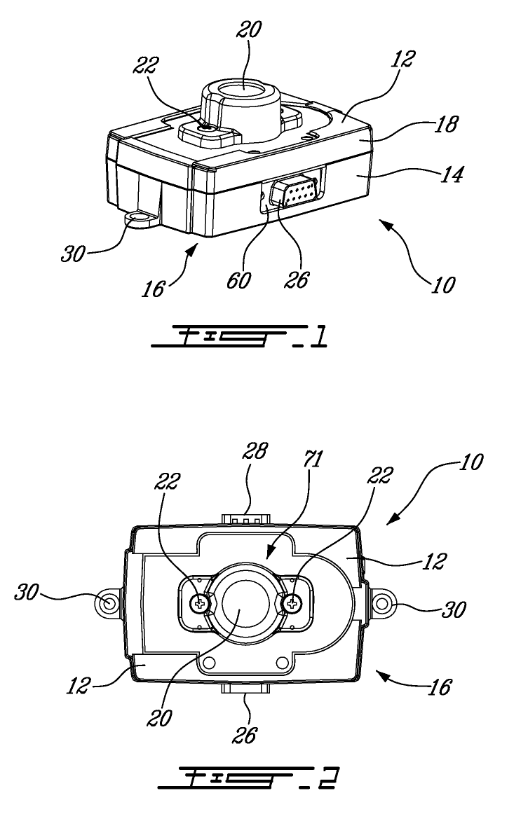

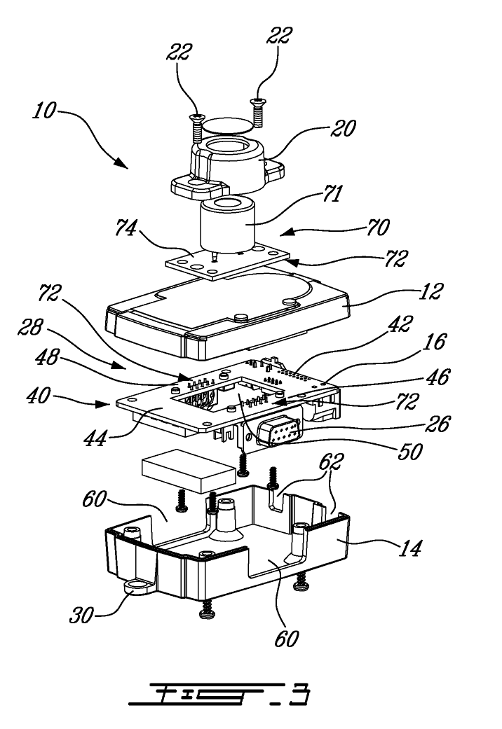

In accordance with a first illustrative embodiment of the present invention there is shown, in FIG. 1 and FIG. 2, a modular sensor mote 10 adapted to sense a physical stimulus and generate a signal indicative of the sensed stimulus. The modular sensor mote 10 is also adapted to transmit data with either a control system or other modular sensor motes 10. A modular sensor mote 10, also known as a sensor ‘node’, is commonly known as a node in a sensor network that is capable of performing some processing, sensory information gathering and communicating with other sensor motes connected in the network.

In the present illustrative embodiment, each modular sensor mote 10 is shaped by a top cover 12 and a bottom cover 14. Both covers 12, 14 are adapted to protect sensor components 16 disposed therein. Both covers 12, 14 are illustratively manufactured in injected plastic and may alternatively be made of other suitable materials.

The covers 12, 14 are removably secured together to allow easy access to the sensor components 16 enclosed therein. The top cover 12 of the present illustrative embodiment is built in two parts, the main part 18 and the secondary part 20. The secondary part 20 is illustratively secured on the main part 18 with screws 22, and offers the advantage of allowing easy access to the interior of the modular sensor mote 10 without completely disassembling the top cover 12 from the bottom cover 14.

A possible alternate embodiment (not shown) provides a top cover 12 made of a single part, requiring the removal of the complete top cover 12 from the bottom cover 14 in order to get access to the sensor components 16 therein.

Still referring to FIG. 1 and FIG. 2, there are provided two connectors 26, 28 disposed on respective sides of the modular sensor mote 10. Advantageously, one of the connectors 26, 28 is a male connector 26 and the other is a corresponding female connector 28. D-sub 9 type connectors 26, 28 are provided with the present illustrative embodiment. Other connectors that are suitable form performing similar functions are also encompassed by the present invention. Furthermore, it is to be understood that in alternative embodiment the modular sensor mote 10 may be provided with a single connector, either a male connector 26, a female connector 28 or some other type of connector.

Additionally, the modular sensor mote 10 is provided with at least one anchoring portions 30 adapted to secure the modular sensor mote 10 to a surface or an object. Other means for securing the modular sensor mote 10 that are not mentioned here will become apparent to a skilled reader without departing from the scope of the present invention.

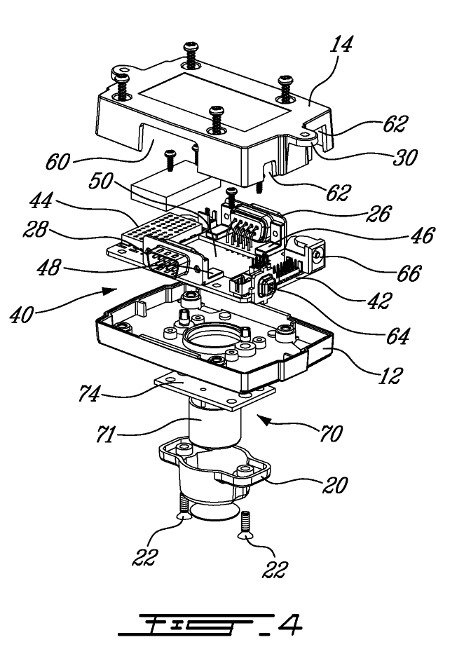

FIG. 3 and FIG. 4 show an exploded view of the modular sensor mote 10 of the preceding figures. As it can be appreciated in these two figures, the electronic components 16 of the present illustrative embodiment include an electronic board 40 provided with five distinct portions. A power management portion 42 is located on one side of the electronic board 40. On the opposite side of the power management portion 42 is located a wireless communication portion 44. Between the power management portion 42 and the wireless communication portion 44 is provided two connector portions 46, 48. A sensor receiving portion 50 is provided in the center of the electronic board 40, bordered by the other portions 42, 44, 46, 48.

The power management portion 42 and the wireless communication portion 44 are disposed on opposite sides thereof to help prevent interferences therebetween. This way, the wireless communication portion 44 is less influenced by the electromagnetic field generated by the power management portion 42 and the electromagnetic field caused by the wireless communication portion 44 has less effect on the other surrounding portions 42, 46, 48.

The two connector portions 46, 48 are disposed on the electronic board 40, inside the modular sensor mote 10, so as to support respective connectors 26, 28 in such a way that they extend through the modular sensor mote's 10 bottom cover 14 through corresponding openings 60. In an alternative embodiment, the openings 60 may be performed in the modular sensor mote's top cover 12 or extend through both covers 12, 14 without departing from the scope of the present invention. The connectors 26, 28, which are secured to the electronic board 40, are adapted to bear mechanical loads to, at least partially, secure the modular sensor mote 10 in a desired position. The interaction between the connectors 26, 28 and the openings 60 provides additional mechanical interaction between the connectors 26, 28 and the covers 12, 14, to limit the mechanical stress transferred to the electronic board 40.

Additional openings 62 are defined in one or both covers 12, 14. The additional openings 62 provide access to a power switch 64 to selectively power the modular sensor mote 10 and an electrical connector 66 to bring external power to the modular sensor mote 10. The power brought through the electrical connector 66 is adapted to be shared with other sensor motes 10 connected through the connectors 26, 28. Other openings can be provided within the covers 12, 14 to achieve various additional functions.

Still referring to FIG. 3 and FIG. 4, it may be observed that a sensor element 70 is adapted to be removably connected within the sensor receiving portion 50 of the electronic board 40. The sensor element 70 as illustrated in the present illustrative embodiment comprises a sensor 71 and a signal converter 74 adapted to convert signals between the sensor 71 and the electronic board 40. The signal converter 74 is also used to interconnect the sensor element 70 with the sensor receiving portion 50 and can be embodied in various suitable configurations. The signal converter 74 provides a series of sensor element connectors 72 adapted to transmit signal and/or power between the sensor 71 and the electronic board 40. The sensor element 70 could alternatively include only a sensor 71 adapted to communicate directly with the electronic board 40 without departing from the present invention. In the present illustrative embodiment, the sensor element 70 comprises a gas sensor 71 adapted to sense a level of one, or many gases, in the ambient air surrounding the sensor element 70 and a signal converter 74 adapted to transmit the sensor's signal to the electronic board 40.

The exterior configuration of the exemplary sensor element 70 changes, among other considerations, according to the nature of the sensor 71. In this embodiment, the exterior shape of the gas sensor 71 is cylindrical and the shape of the top cover 12 is shaped accordingly. In so doing, the exterior shape of the top cover 12 (or the bottom cover 14) reduces the volume of the modular sensor mote 10 while providing insights as to which sensor 71 is assembled in the modular sensor mote 10.

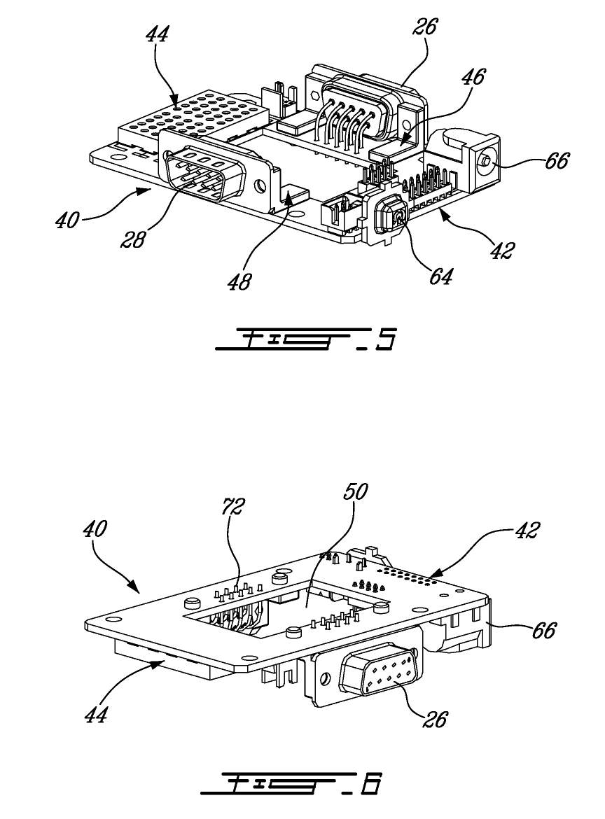

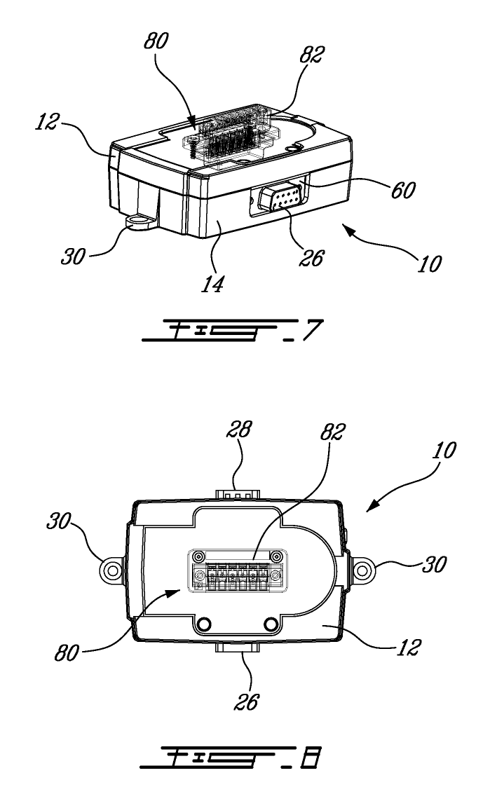

FIG. 5 and FIG. 6 show detailed views of the electronic board 40 discussed above.

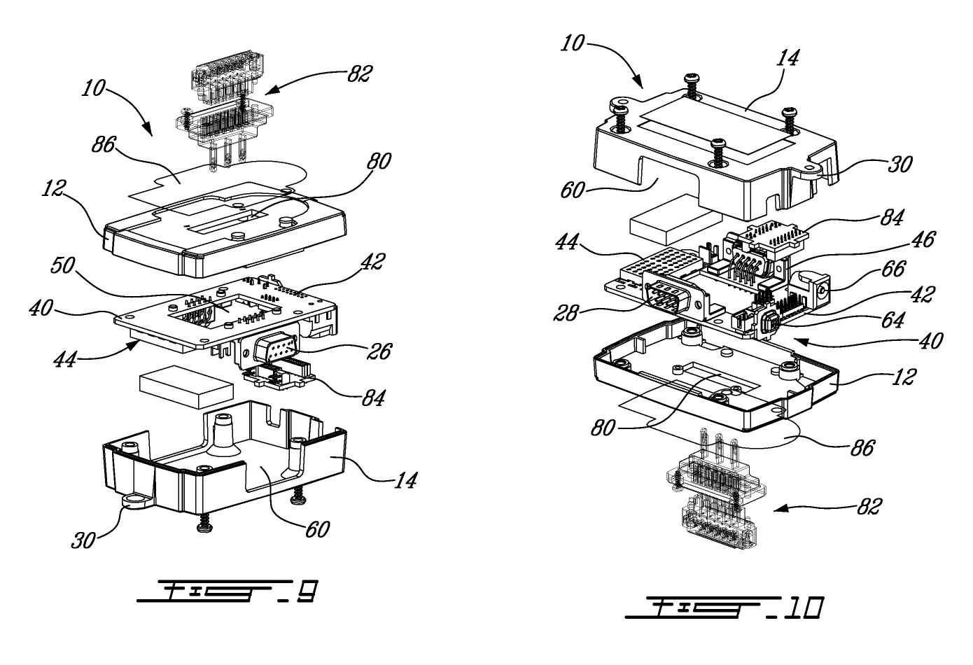

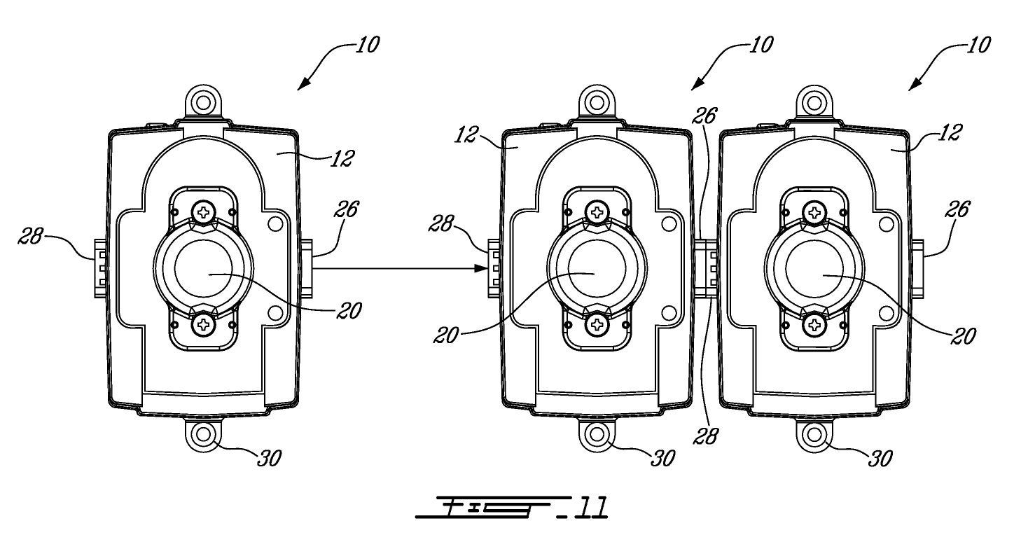

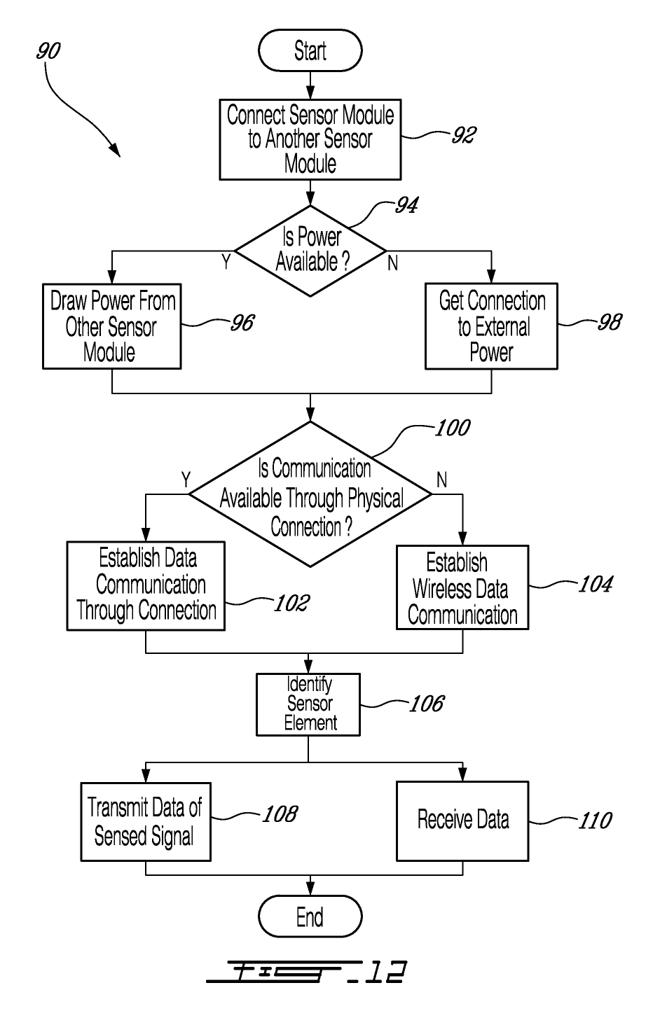

Turning now to FIG. 7 through FIG. 10, there is depicted an alternate illustrative embodiment of the modular sensor mote 10. In this illustrative embodiment, an opening 80 performed in the top cover 12 allows the protrusion from the electronic board 40 of a connector 82 with its associated extension BUS 84 (best seen in FIG. 9 and FIG. 10). In the present illustrative embodiment, the associated extension BUS 84 is a RTD expansion board. A cosmetic layer 86 is also provided on the surface of the top cover 12.

FIG. 11 illustrates an arrangement of sensor motes 10 connected together via their respective connectors 26, 28. This type of solid connection between two or more sensor motes 10 provides power and data transfer capability across the modular sensor motes 10. Also, the mechanical connection with the illustrated D-sub 9 connectors 26, 28 offers significant mechanical support to each sensor mote 10.

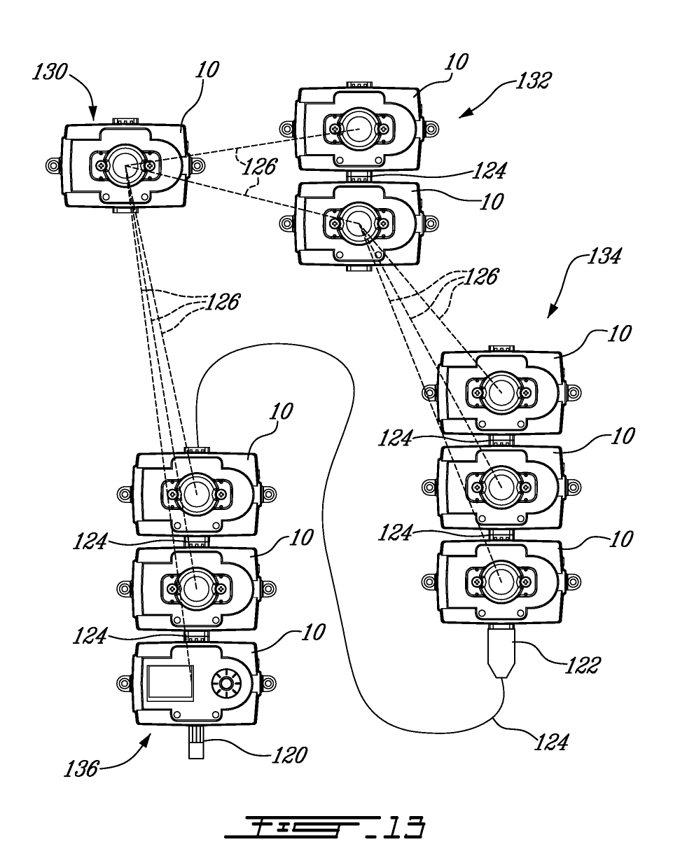

FIG. 12 shows a flow diagram of an exemplary process 90 for physically connecting two or more sensor motes 10. The steps of the process 90 are indicated by blocks 92 to 110.

The process 90 begins, at block 92, with the connection of a modular sensor mote 10 to another sensor mote 10 similar to the illustrative connection among sensor motes 10 of FIG. 11.

Then, at block 94, the process 90 verifies if power can be drawn from the physical connection. If so, the process 90 proceeds to block 96 where the connected sensor mote 10 draws power from the other sensor mote 10. Conversely, if no power is available, the process 90 proceeds to block 98 where external power is required through the electrical connector 66 (best seen in FIG. 5). The process 90 then proceeds to block 100.

At block 100, the process 90 verifies if data can be communicated through the physical connection. If so, data communication is sent, at block 102, through the physical connection. Conversely, if no data communication can be achieved through the physical connection, wireless data communication is enabled/used, at block 104. The process 90 then proceeds to block 106.

At block 106, once connected, the modular sensor mote 10 is identified and data is transmitted, at block 108, and/or received, at block 110.

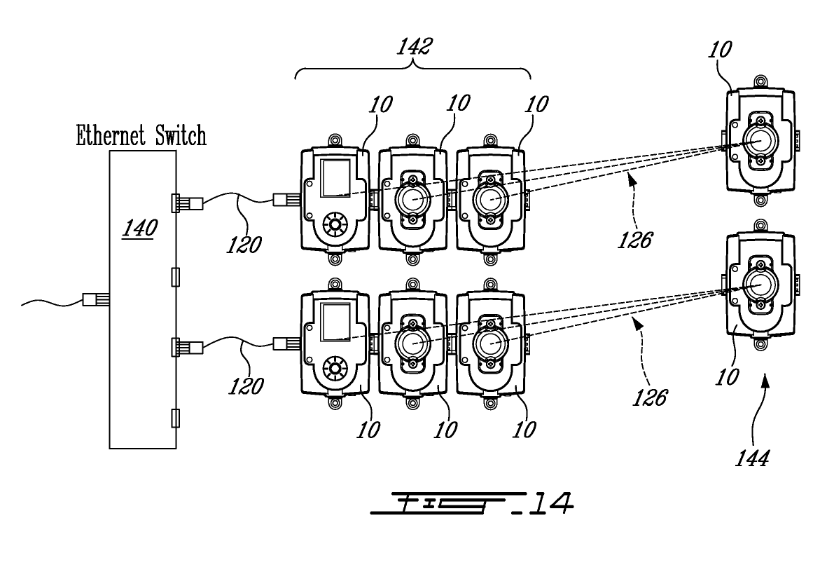

FIG. 13 illustrates a modular sensor motes 10 layout using a combination of wired 124 and/or wireless 126 connections. Wired connections 124 can be achieved through direct sensor mote-to-sensor mote connection, using an intervening power over BUS connection 122 or using a power over Ethernet 120 connection.

Different types of connections may be required depending on the required sensor mote 10 installation. For example, in FIG. 13, the modular sensor mote group 136 is located in a server room and thus can be directly connected with through Ethernet connection 120. Another sensor mote group 134 is located in a room near to the server room, allowing access through a wired connection 124. The modular sensor mote group 132 is located in a remote room where no Ethernet network is accessible. The wireless connection 126 will be preferred in that situation. Finally, sensor mote 130 is located outside of the building and also uses a wireless connection 126 to avoid bringing a network cable outside the building.

FIG. 14 shows an alternate modular sensor motes 10 layout connected in series to the same Ethernet switch 140. The modular sensor motes 10 of modular sensor motes group 142 are directly connected to the Ethernet switch 140 via Ethernet connection 120, while the modular sensor motes 10 of modular sensor motes group 144 are wirelessly connected to the modular sensor motes 10 of modular sensor motes group 142 via wireless connections 126.

It is to be understood that, in an alternative embodiment, the modular sensor mote 10 may include one of at least one connector portion with an associated connector or a wireless communication management portion for communicating with other modular sensor motes 10 and/or a control system.

The description and the drawings that are presented herein are meant to be illustrative of the present invention. They are not meant to be limiting of the scope of the present invention. Modifications to the embodiments described may be made without departing from the present invention, the scope of which is defined by the following claims:

What is claimed is:

1. A modular sensor mote, comprising:
an electronic board having:
one of at least one connector portion with an associated connector and a wireless communication management portion;
a power management portion; and
a sensor receiving portion adapted for receiving a sensor element;
wherein the electronic board is adapted to electrically connect the connector portion, the power management portion and the sensor receiving portion.

2. The modular sensor mote of claim 1, comprising at least one connector portion with an associated connector and a wireless communication management portion.

3. The modular sensor mote of claim 2, comprising two connector portions.

4. The modular sensor mote of claim 3, wherein the connectors are adapted to cooperate with connectors of an adjacent modular sensor mote.

5. The modular sensor mote of claim 3, wherein the sensor receiving portion is substantially defined between the connector portions, the wireless communication management portion and the power management portion.

6. The modular sensor mote of claim 3, wherein the modular sensor mote is adapted to communicate via at least one of the connectors.

7. The modular sensor mote of claim 6, wherein the modular sensor mote is adapted to communicate with another modular sensor mote.

8. The modular sensor mote of claim 6, wherein the modular sensor mote is adapted to communicate with a control system.

9. The modular sensor mote of claim 3, wherein the modular sensor mote is adapted to communicate via the wireless communication management portion.

10. The modular sensor mote of claim 9, wherein the modular sensor mote is adapted to communicate with another modular sensor mote.

11. The modular sensor mote of claim 9, wherein the modular sensor mote is adapted to communicate with a control system.

12. The modular sensor mote of claim 3, wherein at least one of the connectors is adapted to transmit power and data.

13. The modular sensor mote of claim 3, wherein the connectors are D-sub 9 connectors.

14. The modular sensor mote of claim 13, wherein one of the connector is a male connector and the other connector is a female connector.

15. The modular sensor mote of claim 3, wherein the connectors are adapted to bear mechanical loads to, at least partially, secure the modular sensor mote in a desired position.

16. The modular sensor mote of claim 3, wherein the power management portion and the wireless communication portion are located on opposite sides of the electronic board.

17. The modular sensor mote of claim 3, further comprising at least one anchoring portion adapted to secure the modular sensor mote to a surface.

18. The modular sensor mote of claim 3, further comprising an electrical connector for supplying electrical power to the modular sensor mote and a power switch to selectively power the modular sensor mote.

19. The modular sensor mote of claim 3, further comprising a sensor element removably connected to the sensor receiving portion.

20. The modular sensor mote of claim 19, wherein the sensor element is selected from a group consisting of a gas detection element, a temperature detection element and a connector element.

21. The modular sensor mote of claim 19, wherein the sensor element includes a signal converter adapted to convert signals between the sensor element and the electronic board.
